(19) United States
(12) Patent Application Publication
(10) Pub. No.: US 2025/0341602 A1
(43) Pub. Date: Nov. 6, 2025

(54) Magnetic Resonance Apparatus with a Laser Marking Unit

(71) Applicant: Siemens Healthineers AG, Forchheim (DE)

(72) Inventor: Ralph Kimmlingen, Zirndorf (DE)

(73) Assignee: Siemens Healthineers AG, Forchheim (DE)

(21) Appl. No.: 19/195,871

(22) Filed: May 1, 2025

(30) Foreign Application Priority Data
May 6, 2024 (EP) 24174285.7

(51) Int. Cl. G01R 33/58; G01R 33/54

(52) U.S. Cl. CPC G01R 33/58; G01R 33/543

(57) ABSTRACT

A magnetic resonance apparatus is described that comprises a scanner unit, a patient receiving area at least partially surrounded by the scanner unit, a patient support device that has a movable patient table embodied to be inserted into the patient receiving area, and a position-determining unit embodied to determine a position of the patient table with respect to the scanner unit, and which comprises a laser marking unit. The position-determining unit comprises a calibration unit for calibrating the laser marking unit.

### CROSS-REFERENCE TO RELATED APPLICATIONS

The present application claims priority to and the benefit of European patent application no. EP 24174285.7, filed on May 6, 2024, the contents of which are incorporated herein by reference in their entirety.

### TECHNICAL FIELD

The present disclosure relates to a magnetic resonance apparatus with a scanner unit, a patient receiving area at least partially surrounded by the scanner unit, a patient support device which has a movable patient table which is embodied to be inserted into the patient receiving area, and a position-determining unit which is embodied to determine a position of the patient table with respect to the scanner unit and comprises a laser marking unit.

### BACKGROUND

For a magnetic resonance examination, a patient is first positioned on a patient table of a patient support device and then the patient table is inserted together with the patient into the patient receiving area, until the patient, in particular a region of interest of the patient, is positioned in the isocenter of the magnetic resonance apparatus. For correct positioning of the patient, in particular the region of interest of the patient, within the isocenter, the magnetic resonance apparatus has a laser marking unit. By means of the laser marking unit, a laser cross is first projected onto the region of interest of the patient and/or onto a local radio-frequency coil positioned around the region of interest of the patient. Herein, a distance of the laser projection from the isocenter is known to the magnetic resonance apparatus, so that the patient, in particular the region of interest of the patient, can then be positioned in the isocenter.

Such a laser marking unit is arranged in the area of an input opening on the scanner unit. Herein, the laser marking unit is arranged on a housing element that is arranged around the input opening, for example in a tunnel-shaped housing element and/or an insert funnel arranged above the input opening. For this purpose, the housing element preferably has a receiving area that is open at the bottom for receiving the laser marking unit.

The position of the laser marking unit is determined very precisely during calibration measurements in order, for example, to position a measuring phantom with high accuracy in the magnetic center of the scanner unit, in particular a main magnet of the scanner unit. Herein, many measurement steps in the quality assurance of individual components are based on very precise adjustment of the laser marking unit and lead to potentially incorrect results if the position of the laser marking unit is readjusted or changed over time. For example, incorrect positioning of the laser marking unit can lead to problems during regular measurements for quality assurance of local radio-frequency coils. Since a change in the position of the laser marking unit as a source of error cannot be immediately recognized by medical operators, this is usually followed by a complex and lengthy troubleshooting process, which can even lead to expensive coil replacement.

The correction of a position of the laser marking unit requires a service call, during which a service technician has to manually correct the position of the laser marking unit on the scanner unit on site. However, such a correction is very time-consuming and expensive.

### SUMMARY

The present disclosure is based on the object of enabling a user to easily capture and/or correct positioning errors of the laser marking unit. The object is achieved by the features of the embodiments as described herein, including the claims.

The disclosure is based on a magnetic resonance apparatus with a scanner unit, a patient receiving area at least partially surrounded by the scanner unit, a patient support device which has a movable patient table which is embodied to be inserted into the patient receiving area and a position-determining unit which is embodied to determine a position of the patient table with respect to the scanner unit and comprises a laser marking unit. According to the disclosure, the position-determining unit comprises a calibration unit for calibrating the laser marking unit.

The magnetic resonance apparatus may e.g. comprise a medical and/or diagnostic magnetic resonance apparatus which is configured and/or embodied to capture medical and/or diagnostic image data, e.g. medical and/or diagnostic magnetic resonance image data, of a patient. The magnetic resonance apparatus comprises the scanner unit for this purpose. The scanner unit may e.g. comprise a magnet unit for capturing the medical and/or diagnostic image data. Advantageously, in this case, the scanner unit, e.g. the magnet unit, comprises a main magnet, a gradient coil unit, and a radio-frequency antenna unit. The radio-frequency antenna unit may be permanently arranged within the scanner unit and is configured and/or embodied to emit an excitation pulse.

The main magnet is embodied (e.g. configured) to generate a homogeneous main magnetic field with a defined magnetic field strength, such as, for instance, a magnetic field strength of 3 T or 1.5 T, etc. In an embodiment, the main magnet is embodied to generate a strong and constant main magnetic field. The homogeneous main magnetic field may e.g. be arranged and/or located within the patient receiving area of the magnetic resonance apparatus. The gradient coil unit is embodied to generate magnetic field gradients that are used for spatial encoding during imaging.

The patient receiving area is configured and/or embodied to receive the patient, e.g. the region of interest of the patient, for a medical magnetic resonance examination. The patient receiving area may e.g. comprise the area that is available to the patient during a magnetic resonance examination. For example, for this purpose, the patient receiving area may be cylindrical in shape and/or surrounded cylindrically by the scanner unit, e.g. the magnet unit, of the magnetic resonance apparatus.

A field of view (FoV) and an isocenter of the magnetic resonance apparatus may e.g. be arranged within the patient receiving area. The FoV may e.g. comprise a capturing region of the magnetic resonance apparatus within which the conditions for capturing medical image data, e.g. magnetic resonance image data, are present within the patient receiving area, such as a homogeneous main magnetic field. The isocenter of the magnetic resonance apparatus may e.g. comprise the area and/or point within the magnetic resonance apparatus that has the optimal and/or ideal conditions for capturing medical image data. The isocenter may e.g. comprise the most homogeneous magnetic field area within the magnetic resonance apparatus.

To position the patient, e.g. the region of interest of the patient, within the patient receiving area the magnetic resonance apparatus has the patient support device. The patient support device is embodied to support the patient within the patient receiving area. For this purpose, the patient support device has a movable patient table which is e.g. embodied as movable within the patient receiving area of the magnetic resonance apparatus. In this case, the patient table is embodied as movable in the longitudinal direction of the patient receiving area and/or in the z-direction within the patient receiving area. For a magnetic resonance examination, the patient is positioned on the patient table of the patient support device and additional units required for the magnetic resonance examination are also positioned on the patient table or on the patient. Then, the region of interest is positioned with respect to the scanner unit, e.g. with respect to the isocenter of the magnet unit, by means of the position-determining unit, e.g. the laser marking unit, and the patient table moves together with the patient into the patient receiving area until the region of interest of the patient is arranged within the isocenter of the magnetic resonance apparatus.

The position-determining unit is embodied to determine the position of the patient table with respect to the scanner unit. In an embodiment, the position-determining unit is embodied to determine a position of the region of interest with respect to the isocenter of the scanner unit. For this purpose, the position-determining unit has the laser marking unit. The laser marking unit may be arranged in a housing of the scanner unit above an input opening of the patient receiving area and emits a laser beam, for example a cross-shaped laser beam, vertically downward to determine the position. The laser marking unit projects a laser marking, for example the cross-shaped laser beam, onto the region of interest of the patient and/or a local radio-frequency coil arranged around the region of interest of the patient. Herein, the patient table is moved back and forth by a user until the laser projection coincides with the region of interest of the patient and/or a local radio-frequency coil arranged around the region of interest. A distance between the position of the laser projection on the patient table and the isocenter of the scanner unit is defined in such a way that, after marking the region of interest by means of the laser marking unit, the patient table is inserted into the patient receiving area until the region of interest is arranged within the isocenter.

In addition, the position-determining unit has a calibration unit, wherein the calibration unit is embodied to calibrate the laser marking unit. In an embodiment, the calibration unit is used to calibrate a position of the laser marking unit, e.g. a position of the laser marking unit with respect to the isocenter of the scanner unit. In an embodiment, the calibration unit is embodied in such a way that a user, e.g. a medical operator performing a magnetic resonance examination, is able to calibrate the laser marking unit.

The disclosure has the advantage that positioning errors of the laser marking unit can be easily detected and/or corrected. For example, a user such as a medical operator for instance, can easily detect and correct positioning errors of the laser marking unit by means of the calibration unit. In addition, it is advantageously possible to dispense with time-consuming and expensive maintenance by service personnel to detect positioning errors of the laser marking unit. For example, a calibration measurement of the laser marking unit may be performed directly by a medical operator at defined intervals, for example every three months. In addition, a calibration measurement of the laser marking unit may also be performed directly by a medical operator during and/or before defined workflow steps, for example before measurement steps for quality assurance of local radio-frequency coils and/or adjustment measurements.

In an advantageous development of the magnetic resonance apparatus, it can be provided that the calibration unit comprises at least one reflector element arranged in a front area of the movable patient table. The reflector element may e.g. be embodied to reflect the laser beam emitted by the laser marking unit in the direction of the patient table. In an embodiment, for this purpose the reflector element may be arranged on an upward-facing surface of the front area of the patient table so that a calibration laser beam striking the reflector element is substantially reflected by 180°. Herein, the reflector element can also be embodied in such a way that the calibration beam of a correctly positioned laser marking unit is reflected at a defined angle, for example 185°. In an embodiment, the reflector element is fixed at a certain and/or defined position on the front area of the movable patient table, so that the reflector element is always arranged at the same position on the patient table for different calibrations. In addition, this enables the same distance to be maintained between the reflector element and the isocenter of the magnet unit. In this way, the reflector element is advantageously arranged in an area of the patient table that is clearly visible for calibration measurements and is not covered by a measurement object, for example a measurement phantom.

The front area of the patient table may e.g. comprise the area of the patient table that is located at the front of the patient table when the patient table is inserted into the patient receiving area. In other words, the front area of the patient table comprises the area that is the first to be inserted into the patient receiving area when the patient table is inserted into the patient receiving area.

In an advantageous development of the magnetic resonance apparatus, it can be provided that the calibration unit comprises at least one sensor element which is embodied to capture a calibration laser beam. The calibration laser beam may e.g. comprise a laser beam that is emitted by the laser marking unit for calibration of the laser marking unit and/or during a calibration measurement of the laser marking unit. In an embodiment, the calibration laser beam is reflected by the reflector element prior to being captured by means of the at least one sensor element in the direction of the sensor element. This embodiment of the disclosure enables simple and direct capturing of the calibration laser beam during a calibration measurement.

In an advantageous development of the magnetic resonance apparatus, it can be provided that the at least one sensor element comprises a photodiode with a threshold value circuit. A threshold value circuit compares an output variable provided by the photodiode with a threshold value, wherein the output variable provided by the photodiode is dependent on a captured signal, for example the captured calibration laser beam. The photodiode's output variable can, for example, be an output voltage or an output current. A switching operation within the threshold value circuit is triggered when the output variable measured by the photodiode exceeds or falls below a preset threshold value. For instance, the output variable of the photodiode may vary if the reflected calibration beam no longer strikes the photodiode exactly or misses it completely due to a positioning error and/or a change of position of the laser marking unit. As an alternative to a photodiode, the at least one sensor element may also have a phototransistor and/or a CMOS element, and/or other suitable additional or alternative sensor elements that appear advisable to the person skilled in the art. This enables a positioning error of the laser marking unit to be captured and/or detected particularly directly during a calibration measurement.

In an advantageous development of the magnetic resonance apparatus, it can be provided that the calibration unit comprises a control unit, wherein the control unit is connected to the at least one sensor element for data exchange, wherein the control unit is embodied to generate output information to the user depending on an output signal of the threshold value circuit. In an embodiment, the control unit is embodied to generate output information to the user if incorrect positioning and/or a change in position of the laser marking unit is detected during a calibration measurement. In addition, the control unit is embodied to provide the output information to an output unit for output to the user. The output information may e.g. be output by means of an output unit, for example a display, of the magnetic resonance apparatus to the user. In addition, the control unit can also generate and provide output information to a user when the laser marking unit is in the correct position during a calibration measurement. In an embodiment, the output information informs the user about the position, e.g. a current position, of the laser marking unit during a calibration measurement, for example whether the laser marking unit is in a correct position or the laser marking unit is incorrectly positioned. The output information to the user also enables the user to make a correction, e.g. a position correction, of the laser marking unit. Thus, in this case the user can always be informed of the current position of the laser marking unit during a position correction of the laser marking unit, e.g. whether it is correct or whether the laser marking unit is still incorrectly positioned.

The control unit comprises at least one computing module and/or processor. Thus, the control unit may e.g. be embodied to execute computer-readable instructions. For instance, the control unit may comprise a memory unit, wherein computer-readable information is stored on the memory unit, and wherein the control unit is embodied to load the computer-readable information from the memory unit and to execute the computer-readable information. In this way, the control unit is embodied to generate and provide output information to the user depending on an output signal of the threshold value circuit.

The components of the control unit may e.g. predominately be embodied in the form of software components. In principle, however, some of these components can also be realized in the form of software-supported hardware components, for example FPGAs or the like, e.g. when particularly fast calculations are required. Likewise, the required interfaces can be embodied as software interfaces, for example if it is only a matter of transferring data from other software components. However, these may also be embodied as hardware interfaces that are actuated by suitable software. Of course, it is also conceivable for several of the aforementioned components to be realized together in the form of a single software component or software-supported hardware component.

Herein, the control unit of the calibration unit may be comprised by a system control unit of the magnetic resonance apparatus and integrated therein. Alternatively, the control unit of the calibration unit may be embodied separately from the system control unit of the magnetic resonance apparatus (e.g. as a separate controller).

In an advantageous development of the magnetic resonance apparatus, it can be provided that the at least one sensor element is arranged on the laser marking unit. Herein, the at least one sensor element can be arranged adjacent to the laser marking unit, e.g. directly next to the laser marking unit. In an embodiment, the at least one sensor element is arranged on the laser marking unit in such a way that, when the position of the laser marking unit is corrected, the at least one sensor element undergoes a change in position together with the laser marking unit. Arranging the at least one sensor element on the laser marking unit advantageously enables simple and direct capturing of the calibration laser beam, e.g. the calibration laser beam reflected by the reflector element, to be achieved during a calibration measurement. A further advantage is that the reflector element for reflecting the calibration laser beam can be easily and quickly attached to a horizontal surface of the patient table. This advantageously enables the need for complex adjustment of the reflector element to adjust a defined reflection angle, e.g. a reflection angle that differs from 180°, to be eliminated.

In an advantageous development of the magnetic resonance apparatus, it can be provided that the scanner unit comprises a housing unit, wherein the housing unit comprises a housing element with a receiving area for receiving the laser marking unit, wherein the laser marking unit is arranged together with the at least one sensor element of the calibration unit in the receiving area of the housing element. In an embodiment, the housing element with the receiving area for receiving the laser marking unit is arranged in a transition area between the patient receiving area and a front side of the scanner unit. Herein, particularly advantageously, the housing element is arranged around an insertion opening of the patient receiving area and comprises, for example, a funnel-shaped housing element. In addition to the housing element arranged around the insertion opening of the patient receiving area, the housing unit may also have further units, such as a front cladding unit, a rear cladding unit, a side cladding unit, etc., which are embodied to clad a front side, a rear side, and side areas of the scanner unit, respectively, of e.g. the magnet unit. The insertion opening of the patient receiving area comprises a front-side opening of the patient receiving area through which the patient table is inserted into the patient receiving area. In addition, the patient receiving area may also comprise a rear-side opening. In this case, the receiving area for receiving the laser marking unit may be integrated into the housing element and may e.g. be open at the bottom so that the laser beam for marking a region of interest can exit the receiving area downward in the direction of the patient table, e.g. vertically downward. This makes it possible to achieve a protected arrangement of both the laser marking unit and the sensor element of the calibration unit.

In an advantageous development of the magnetic resonance apparatus, it can be provided that the calibration unit comprises at least one adjusting element that is embodied to adjust a position of the laser marking unit in at least one direction. The at least one direction in which the position of the laser marking unit can be adjusted by means of the adjusting element may e.g. comprise a direction parallel to a z-direction of the scanner unit. Herein, the z-direction of the scanner unit is parallel to a longitudinal direction of the patient receiving area and/or an insertion direction of the patient table into the patient receiving area. The adjusting element may e.g. be embodied for manual adjustment and/or correction of the position of the laser marking unit by a user, e.g. a medical operator. In an embodiment, during a calibration measurement, the user may use the adjusting element to correct the position of the laser marking unit in the at least one direction if the laser marking unit is incorrectly positioned. This enables simple and direct correction of incorrect positioning of the laser marking unit by the user.

In an advantageous development of the magnetic resonance apparatus, it can be provided that the at least one adjusting element has an adjusting wheel for setting the position of the laser marking unit in the at least one direction. The adjusting wheel can, for example, have teeth, for example on an outer side of the adjusting wheel. For example, the teeth of the adjusting wheel can engage in corresponding teeth of a toothed rack, so that turning the adjusting wheel can effect an axial movement of the toothed rack. Herein, the laser marking unit can be arranged and/or supported on the toothed rack of the adjusting element, so that turning the adjusting wheel can effect an axial movement of the toothed rack and thus the laser marking unit. In addition, the adjusting wheel can also be connected to a shaft, wherein the shaft engages in corresponding teeth for the axial movement of the laser marking unit. In addition, further embodiments, e.g. embodiments that differ from an adjusting wheel, of the adjusting element are conceivable in an alternative embodiment of the adjusting element. The adjusting wheel can enable a user to easily and directly adjust and/or correct the position of the laser marking unit manually. In addition, this also enables the provision of particularly fine and/or precise adjustment in small steps.

In an advantageous development of the magnetic resonance apparatus, it can be provided that the at least one adjusting element is embodied to adjust and/or to correct the position of the laser marking unit in the at least one direction by any suitable maximum range of values (e.g. per direction), such as for example a maximum of ±1 mm, a maximum of ±2 mm, a maximum of ±3 mm, a maximum of ±4 mm, a maximum of ±5 mm, up to ±6 mm, etc. This enables the provision of simple and cost-effective correction directly by a user for small corrections and/or small positioning errors of the laser marking unit.

In an advantageous development of the magnetic resonance apparatus, it can be provided that the at least one adjusting element is arranged on the laser marking unit. Herein, the adjusting element can also be arranged at least partially together with the laser marking unit in the receiving area of the housing element, wherein the adjusting element, e.g. the adjusting wheel of the adjusting element, can be operated from the outside. In this way, robust adjustment and/or correction of a position of the laser marking unit can be provided for a user, since long transmission paths and/or transmission elements, for example a drive shaft, are advantageously dispensed.

In this way, the calibration unit can be used to compensate a position correction of the laser marking unit in a range of up to any suitable maximum range, such as for instance ±6 mm. For instance, in this case, the position correction of the laser marking unit can be performed directly by a user, e.g. a medical operator. This can advantageously save the need for a service technician. However, if there are larger positioning errors and/or differences from the target position of the laser marking unit, e.g. differences of more than a suitable threshold value (e.g. ±6 mm), it may still be advisable to call in a service technician. But such large differences are usually caused by an angular error in the suspension of the laser marking unit. In order to correct such large differences, the calibration device could, for example, be equipped with a Cardan suspension and/or a second adjusting wheel for correcting the tilt angle of the laser marking unit, so that the position of the laser marking unit can still be corrected directly by a user.

### BRIEF DESCRIPTION OF THE DRAWINGS

Further advantages, features, and details of the disclosure emerge from the exemplary embodiment described below and from the drawings.

The drawings show:

FIG. 1 illustrates a schematic representation of an example magnetic resonance apparatus according to the disclosure with an example position-determining unit; and

FIG. 2 illustrates a schematic representation of the example position-determining unit with an example laser marking unit and an example calibration unit.

### DETAILED DESCRIPTION OF THE DISCLOSURE

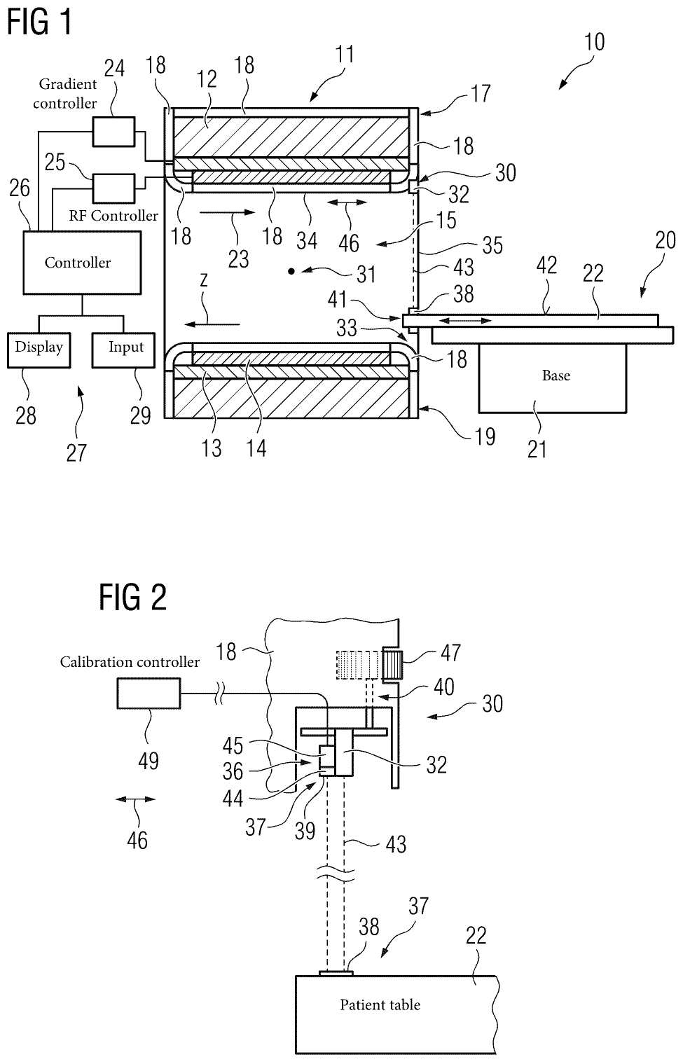

FIG. 1 illustrates a schematic representation of an example magnetic resonance apparatus according to the disclosure with an example position-determining unit. More specifically, FIG. 1 is a schematic representation of a magnetic resonance apparatus 10. The magnetic resonance apparatus 10 comprises a scanner unit (also referred to herein as a scanner) formed by a magnet unit (also referred to herein as a magnet assembly) 11 with a main magnet 12, a gradient coil unit (also referred to herein as a gradient coil set or a gradient coil assembly) 13 and a radio-frequency antenna unit (also referred to herein as an RF antenna) 14. In addition, the magnetic resonance apparatus 10 has a patient receiving area 15 for receiving a patient for a magnetic resonance examination. In the present exemplary embodiment, the patient receiving area 15 is cylindrical and is enclosed in a circumferential direction cylindrically by the magnet unit 11. In principle, however, a different embodiment of the patient receiving area 15 is conceivable at any time. The scanner unit of the magnetic resonance apparatus 10 furthermore has a housing unit (also referred to herein as a housing or housing assembly) 17 embodied to clad the scanner unit. For this purpose, the housing unit 17 has a plurality of housing elements (also referred to herein as housing portions) 18, e.g. front cladding elements for cladding a front side 19 of the magnet unit 11, rear cladding elements for cladding a rear side of the magnet unit 11, side cladding elements for cladding the side surfaces of the magnet unit 11, and an enclosure 34 surrounding the patient receiving area 15.

For positioning the patient, e.g. a region of interest of the patient, within the patient receiving area 15, the magnetic resonance apparatus 10 has a patient support device (also referred to herein as a patient support or patient support assembly) 20. The patient support device 20 has a base unit 21 and a patient table 22 that is movable with respect to the base unit 21. For positioning the patient, e.g. the region of interest of the patient, the patient table 22 is embodied movably within the patient receiving area 15. In an embodiment, in this case the patient table 22 is mounted so as to be movable in the direction of a longitudinal extension of the patient receiving area 15 and/or in the z-direction of the magnet unit 11.

The main magnet 12 of the magnet unit 11 is embodied to generate a strong and e.g. constant main magnetic field 23. Herein, the main magnet 12 can, for example, be embodied as a superconducting main magnet 12 or also as a permanent magnet. The gradient coil unit 13 of the magnet unit 11 is embodied to generate magnetic field gradients that are used for spatial encoding during imaging. The gradient coil unit 13 is controlled by means of a gradient control unit (also referred to herein as a gradient controller) 24 of the magnetic resonance apparatus 10. The radio-frequency antenna unit 14 of the magnet unit 11 is embodied to excite a polarization that establishes itself in the main magnetic field 23 generated by the main magnet 12. The radio-frequency antenna unit 14 is controlled by a radio-frequency control unit (also referred to herein as an RF controller) 25 of the magnetic resonance apparatus 10 and radiates radio-frequency magnetic resonance sequences into the patient receiving area 15 of the magnetic resonance apparatus 10.

The magnetic resonance apparatus 10 has a system control unit (also referred to herein as a system controller or simply a controller) 26 for controlling the main magnet 12, the gradient control unit 24, and the radio-frequency control unit 25. The system control unit 26 centrally controls the magnetic resonance apparatus 10, for example in the performance of a predetermined gradient echo sequence. In addition, the system control unit 26 comprises an evaluation unit (not shown in further detail) to evaluate medical image data captured during the magnetic resonance examination.

Furthermore, the magnetic resonance apparatus 10 comprises a user interface 27, which is connected to the system control unit 26. Control information, such as imaging parameters and reconstructed magnetic resonance images, can be displayed for a medical operator on a display unit 28 and/or output unit, for example on at least one monitor, of the user interface 27. In addition, the user interface 27 has an input unit 29 by means of which information and/or parameters can be entered by a medical operator during a measurement process.

In addition, the magnetic resonance apparatus 10 has a position-determining unit (also referred to herein as a position-determiner) 30 (FIG. 1 and FIG. 2), which is embodied to determine a position of the patient table 22 with respect to the scanner unit, e.g. the magnet unit 11. Herein, the position-determining unit 30 is embodied to determine a position of the patient table 22, e.g. the position of a region of interest of the patient, with respect to an isocenter 31 of the magnet unit 11. For this purpose, the position-determining unit 30 has a laser marking unit (also referred to herein as a laser marker) 32. In this case, the laser marking unit 32 is arranged in a housing element (e.g. a housing portion) 18 of the housing unit 17. Herein, the housing element 18 comprises a funnel-shaped housing element 18, e.g. an insert funnel, and is arranged in a transition area 33 between the enclosure 34 surrounding the patient receiving area 15 and the front side 19. Herein, the funnel-shaped housing element 18 surrounds an insertion opening 35 of the patient receiving area 15. The funnel-shaped housing element 18 has a receiving area 36 for receiving the laser marking unit 32. This receiving area 36 is arranged over the insertion opening 35 of the patient receiving area 15, wherein the receiving area 36 is embodied as open at the bottom.

In addition, the position-determining unit 30 has a calibration unit (also referred to herein as a calibrator or calibration assembly) 37 which is embodied to calibrate the laser marking unit 32. In an embodiment, the calibration unit 37 is embodied to calibrate the position of the laser marking unit 32. For this purpose, the calibration unit 37 has a reflector element (also referred to herein as a reflector) 38, a sensor element (also referred to herein as a sensor) 39, and an adjusting element (also referred to herein as an adjustor) 40 (FIG. 2).

The reflector element 38 of the calibration unit 37 is arranged on the movable patient table 22. In an embodiment, the reflector element 38 is arranged in a front area 41 of the movable patient table 22. Herein, the reflector element 38 is arranged on an upward-facing surface 42 of the front area 41 of the patient table 22. The reflector element 38 is embodied to reflect a calibration laser beam 43 emitted by the laser marking unit 32 during a calibration measurement. Herein, the calibration laser beam 43 comprises a laser beam emitted by the laser marking unit 32, which is emitted for calibrating the laser marking unit 32. During a calibration measurement, the patient table 22 is in a defined starting position with respect to the isocenter 31 of the scanner unit. In this starting position of the patient table 22, the reflector element 38 is located vertically below the laser marking unit 32 when the latter is correctly positioned. Hence, a calibration laser beam 43 emitted by the laser marking unit 32, which is emitted vertically downward from the laser marking unit 32, strikes the reflector element 38 and is reflected thereby.

The sensor element 39 of the calibration unit 37 is embodied to capture (e.g. receive) the calibration laser beam 43. In an embodiment, the sensor element 39 is embodied to capture the calibration laser beam 43 reflected by the reflector element 38. Herein, the sensor element 39 is arranged on the laser marking unit 32. In an embodiment, the sensor element 39 is arranged together with the laser marking unit 32 within the receiving area 36 for receiving the laser marking unit 32 on the housing element 18.

The sensor element 39 comprises a photodiode 44 with a threshold value circuit 45. Herein, the threshold value circuit 45 compares an output variable provided by the photodiode 44 with a threshold value, wherein the output variable provided by the photodiode 44 is dependent on an intensity of the captured calibration laser beam 43. The output variable of the photodiode 44 can, for example, comprise an output voltage or an output current. In an embodiment, the output variable of the photodiode 44 varies if the reflected calibration laser beam 43 no longer strikes the photodiode 44 exactly or misses it completely due to a positioning error and/or a change in position of the laser marking unit 32. A switching operation within the threshold value circuit 45 is triggered when the output variable measured by the photodiode 44 exceeds or falls below a preset threshold value.

The adjusting element 40 of the calibration unit 37 is embodied to adjust a position of the laser marking unit 32 in a direction 46. The direction 46 in which the position of the laser marking unit 32 can be adjusted by means of the adjusting element 40, e.g. comprises the z-direction of the scanner unit, e.g. the magnet unit 11. In the present exemplary embodiment, the adjusting element 40 comprises an adjusting wheel 47, wherein, when the adjusting wheel 47 is turned by a user, the laser marking unit 32 is positioned in the z-direction. Herein, the adjusting wheel 47 may include teeth, for example on an outer side of the adjusting wheel 47 which engages in a toothing of the adjusting element 40 on which the laser marking unit 32 is arranged, so that an axial movement of the laser marking unit 32 is effected by turning the adjusting wheel 47. In addition, the adjusting wheel 47 can also be connected to a shaft which engages in a toothing for the axial movement of the laser marking unit 32. In addition, further embodiments of the adjusting element 40 are possible at any time. In an embodiment, when the laser marking unit 32 is positioned in the direction 36, the sensor element 39 arranged on the laser marking unit 32 is also moved.

Herein, the adjusting element 40 is embodied to adjust the position of the laser marking unit 32 and/or to correct the position of the laser marking unit 32 in any suitable number of directions (e.g. the z-direction) by a maximum of any suitable range of values, such as for instance a maximum of ±1 mm, a maximum of ±2 mm, a maximum of ±3 mm, a maximum of ±4 mm, a maximum of ±5 mm, a maximum of ±6 mm, etc.

In addition, the adjusting element 40 is arranged on the laser marking unit 32. In an embodiment, the adjusting element 40 is arranged within the receiving area 36 for receiving the laser marking unit 32 together with the laser marking unit 32 on the housing element 18, wherein a user can operate the adjusting element 40 from the outside.

In an alternative embodiment, the adjusting element 40 can also have an embodiment that differs from an adjusting wheel 47.

In addition, the calibration unit 30 comprises a control unit 49 (also referred to herein as a calibration controller), wherein the control unit 49 is connected to the sensor element 39 for data exchange. Again, the functions of the control unit 49 may additionally or alternatively be performed via the controller 26 of the magnetic resonance apparatus 10, as noted above. For this purpose, the control unit 49 is embodied to generate output information to the user depending on the output signal of the threshold value circuit 45 and provide this for output. The output information may e.g. be output to the user by means of the display unit 28 and/or the output unit of the user interface 27 of the magnetic resonance apparatus 10. In an embodiment, the control unit 49 is embodied to generate output information to the user in the event of incorrect positioning and/or a change in position of the laser marking unit 32 being detected during a calibration measurement. In addition, the control unit 50 can also generate and provide output information to a user in the event of a correct position of the laser marking unit 32 during a calibration measurement. In an embodiment, the output information informs the user of the position, e.g. the current position, of the laser marking unit 32 during a calibration measurement.

The magnetic resonance apparatus 10 illustrated can of course comprise further components typical of magnetic resonance apparatuses 10. In addition, a general mode of operation of a magnetic resonance apparatus 10 is known to the person skilled in the art, so that no detailed description of the further components will be given.

Although the disclosure has been illustrated and described in detail by the preferred exemplary embodiment, the disclosure is not restricted by the disclosed examples and other variations can be derived herefrom by the person skilled in the art without departing from the scope of protection of the disclosure.

The various components described herein may be referred to as “units.” Such components may be implemented via any suitable combination of hardware and/or software components as applicable and/or known to achieve their intended respective functionality. This may include mechanical and/or electrical components, processors, processing circuitry, or other suitable hardware components, in addition to or instead of those discussed herein. Such components may be configured to operate independently, or configured to execute instructions or computer programs that are stored on a suitable computer-readable medium. Regardless of the particular implementation, such units, as applicable and relevant, may alternatively be referred to herein as “circuitry,” “controllers,” “processors,” or “processing circuitry,” or alternatively as noted herein.

Independent of the grammatical term usage, individuals with male, female or other gender identities are included within the term.

What is claimed is:

1. A magnetic resonance apparatus, comprising:
a scanner;
a patient receiving area at least partially surrounded by the scanner; and
a patient support comprising a movable patient table that is configured to be inserted into the patient receiving area; and
a position-determiner configured to determine a position of the patient table with respect to the scanner,
wherein the position-determiner comprises a laser marker and a calibration assembly configured to calibrate the laser marker.

2. The magnetic resonance apparatus as claimed in claim 1, wherein the calibration assembly comprises a reflector arranged in a front region of the movable patient table.

3. The magnetic resonance apparatus as claimed in claim 1, wherein the calibration assembly comprises a sensor that is configured to receive a laser beam.

4. The magnetic resonance apparatus as claimed in claim 3, wherein the sensor comprises a photodiode including a threshold value circuit.

5. The magnetic resonance apparatus as claimed in claim 4, wherein the calibration assembly comprises a calibration controller coupled to the sensor to perform a data exchange, and
wherein the calibration controller is configured to output data based upon an output signal of the threshold value circuit.

6. The magnetic resonance apparatus as claimed in claim 3, wherein the sensor is arranged on the laser marker.

7. The magnetic resonance apparatus as claimed in claim 3, wherein:
the scanner comprises a housing,
the housing comprises a housing portion having a receiving area configured to receive the laser marker, and
the laser marker is arranged with the sensor in the receiving area of the housing portion.

8. The magnetic resonance apparatus as claimed in claim 1, wherein the calibration assembly comprises an adjustor configured to adjust a position of the laser marker in one or more directions.

9. The magnetic resonance apparatus as claimed in claim 8, wherein the adjustor comprises an adjusting wheel configured to adjust the position of the laser marker.

10. The magnetic resonance apparatus as claimed in claim 8, wherein the adjustor is configured to adjust the position of the laser marker in the one or more directions by a maximum of ±1 mm per respective direction.

11. The magnetic resonance apparatus as claimed in claim 8, wherein the adjustor is arranged on the laser marker.
